(19) United States
(12) Patent Application Publication
(10) Pub. No.: US 2025/0259934 A1
(43) Pub. Date: Aug. 14, 2025

(54) ELECTRONIC MODULE AND METHOD OF MANUFACTURING ELECTRONIC MODULE

(71) Applicant: SHINDENGEN ELECTRIC MANUFACTURING CO., LTD., Tokyo (JP)

(72) Inventors: Soichiro UMEDA, Saitama (JP); Atsushi KYUTOKU, Saitama (JP)

(21) Appl. No.: 19/045,547

(22) Filed: Feb. 5, 2025

(30) Foreign Application Priority Data
Feb. 14, 2024 (JP) 2024-020363

(51) Int. Cl. H01L 23/538; H01L 21/48; H01L 23/15; H01L 23/36; H01L 25/07

(52) U.S. Cl. CPC H01L 23/5385; H01L 21/4846; H01L 23/36; H01L 25/072; H01L 23/15

(57) ABSTRACT

To provide an electronic module where a heat radiation surface is disposed on both up and lower surfaces thereof, and the radiation surfaces are mounted in a height direction with high mounting accuracy whereby the electronic module possesses an excellent heat radiation characteristic. The electronic module includes a first board, a first electronic element disposed on the first board, a second board, a second electronic element disposed on the second board, and an internal connection terminal that connects the first board and the second board to each other. The second board includes a protruding portion that protrudes more outside than an outer periphery of the first board as viewed in a plan view.

### CROSS REFERENCE TO RELATED APPLICATIONS

The present application is based on, and claims priority from JP Application Serial Number 2024-020363, filed Feb. 14, 2024, the disclosure of which is hereby incorporated by reference herein in its entirety.

### TECHNICAL FIELD

The present invention relates to an electronic module and a method of manufacturing an electronic module.

### BACKGROUND ART

Conventionally, there has been known an electronic module (semiconductor device) 900 where heat radiation members (back surface metal bodies) 923, 933 are disposed on both surfaces of an electronic module (semiconductor device) 900 so as to radiate heat from both surfaces of the electronic module 900. Patent Literature 1 discloses: a semiconductor element 910 that has electrodes on both surfaces; a pair of boards 920, 930 that are disposed so as to sandwich the semiconductor element 910 therebetween; and an electrically conducive spacer 940 that is interposed between the board 930 and the semiconductor element 910. The boards 920, 930 include: insulation substrates 921, 931; surface metal bodies 922, 932 that are connected to the corresponding electrodes of the semiconductor element 910; heat radiation members 923, 933. Heat generated by the semiconductor element 910 is radiated from both surfaces of the electronic module 900 through the electrically conductive spacer 940, surface metal bodies 922, 932, the heat radiation members 923, 933.

### CITATION LIST

### Patent Literature

[Japanese Patent Literature 1] JP-A-2022-181822

### SUMMARY OF INVENTION

### Technical Problem

However, in a case of an electronic module that radiates heat from both surfaces thereof, it is necessary to bring heat radiation surfaces disposed on both surface of the electronic module into contact with heat sinks (see FIG. 7). Accordingly, a control that restricts a distance between the heat radiation surface and the heat radiation surface within a predetermined tolerance.

On the other hand, in an electronic module on which a plurality of boards are stacked, the electronic module is manufactured by stacking constitutional elements such as the boards, an internal connection terminal, an external connection terminal and the like in a height direction of the electronic module. In the conventional electronic module of a one side heat radiation type, a heat radiation surface is disposed only on one surface of the electronic module and hence, when the internal constitutional elements are stacked, it is not indispensable to perform a strict tolerance control. On the other hand, when the heat radiation surface is disposed on both surfaces of the electronic module, the positions of the heat radiation surfaces that are disposed in the height direction exert a large effect with respect to a heat radiation characteristic and hence, a highly accurate control of the positions of the heat radiation surfaces is requested.

The present invention has been made in view of the above-mentioned drawbacks, and it is an object of the present invention to provide an electronic module where a heat radiation surface is disposed on both surfaces thereof, wherein the heat radiation surface is mounted with high mounting accuracy in a height direction so that the electronic module possesses an excellent heat radiation characteristic. It is another object of the present invention to provide a method of manufacturing an electronic module capable of manufacturing such an electronic module.

### Solution to Problem

An electronic module according to the present invention includes: a first board; a first electronic element that is disposed on the first board; a second board; a second electronic element that is disposed on the second board; and an internal connection terminal that is disposed between the first board and the second board, wherein the second board includes a protruding portion that protrudes more outside than an outer periphery of the first board as viewed in a plan view.

A method of manufacturing an electronic module according to the present invention is the method that uses an assembly jig includes a first mounting portion and a second mounting portion. The method includes: a first board mounting step of mounting a first board on the first mounting portion; an internal connection terminal mounting step of mounting one end of an internal connection terminal on the first board; and a second board mounting step of mounting the second board on an other end of the internal connection terminal and the second mounting portion. The second board has a protruding portion that protrudes more outside than an outer periphery of the first board as viewed in a plan view when the second board is assembled as a part of the electronic module, the second board is mounted on the second mounting portion in a state where the protruding portion is engaged with and is stopped by the second mounting portion, and the second mounting portion is disposed at a predetermined height position from the first mounting portion, and is disposed at a position where the protruding portion is engaged with and is stopped by the second mounting portion as viewed in a plan view.

### Advantageous Effects of the Present Invention

The electronic module according to the present invention includes: the first board, the second board, and the internal connection terminal disposed between the first board and the second board. The second board includes the protruding portion that protrudes more outside than the outer periphery of the first board as viewed in a plan view. The electronic module according to the present invention can mount the first board and the second board in the height direction with high accuracy using the first heat radiation surface of the first board and the protruding portion of the second board. According to the present invention, in the electronic module where the heat radiation surface is disposed on both surfaces of the electronic module, the heat radiation surfaces can be mounted in the height direction with high mounting accuracy and hence, it is possible to provide the electronic module that possesses an excellent heat radiation characteristic.

The method of manufacturing an electronic module according to the present invention is performed using the assembly jig that includes the first mounting portion and the second mounting portion. The method includes: the first board mounting step of mounting the first board on the first mounting portion of the assembly jig; and the second board mounting step of mounting the second board on the second mounting portion. The second board has the protruding portion that protrudes more outside than the outer periphery of the first board as viewed in a plan view when the second board is assembled as the electronic module. The second board is mounted on the second mounting portion is disposed at a predetermined height position from the first mounting portion, and is disposed at a position where the protruding portion is engaged with and is stopped by the second mounting portion as viewed in a plan view. With such a configuration, the first board and the second board can be mounted in a height direction with high accuracy. According to the present invention, in the electronic module where a heat radiation surface is disposed on both surfaces of the electronic module, the heat radiation surfaces are mounted in the height direction with high mounting accuracy and hence, it is possible to realize the method of manufacturing an electronic module that possesses an excellent heat radiation characteristic.

### BRIEF DESCRIPTION OF DRAWINGS

FIG. 1 is a perspective view of an electronic module 1 according to an embodiment. In FIG. 1, among constitutional elements of the electronic module 1, a mold resin 40 is not illustrated.

FIG. 2 is an external appearance view of the electronic module 1 according to the embodiment.

FIG. 3 is a side view illustrating the internal structure of the electronic module 1 according to the embodiment. In FIG. 3, among the constitutional elements of the electronic module 1, the mold resin 40 and some internal connection terminals 36 are not illustrated.

FIG. 4A to FIG. 4C are plan views illustrating variations of protruding portions 25 in the electronic module 1 according to the embodiment. In FIG. 4A to FIG. 4C, among the constitutional elements of the electronic module 1, the mold resin 40, a first external connection terminal 32 and a second external connection terminal 34 are not illustrated. Further, in FIG. 4A to FIG. 4C, a second board 20 is indicated by a solid line, a first board 10 is illustrated by a dotted line. In a portion where the solid line and the dotted line overlap with each other, the dotted line is omitted. FIG. 4A is a view illustrating a mode of the protruding portion 25 in the electronic module 1 according to the embodiment illustrated in FIG. 1 to FIG. 3. FIG. 4B is a view illustrating a mode of the protruding portion 25 in the electronic module according to a first modification. FIG. 4C is a view illustrating a mode of the protruding portion 25 in the electronic module according to a second modification.

FIG. 5 is a view illustrating an example of an assembly jig 50 that can be used for manufacturing the electronic module 1 according to the embodiment.

FIG. 6A to FIG. 6C are views illustrating a method of manufacturing the electronic module 1 according to the embodiment.

FIG. 7 is a view illustrating an electronic module 900 according to the prior art.

### DESCRIPTION OF EMBODIMENTS

Hereinafter, an electronic module and a method of manufacturing an electronic module according to the present invention are described based on embodiments illustrated in the drawings. It is not always the case that all of various constitutional elements described in the embodiments and the combinations thereof are indispensable as means to solve the problems of the present invention.

### Embodiment

### 1. Electronic Module

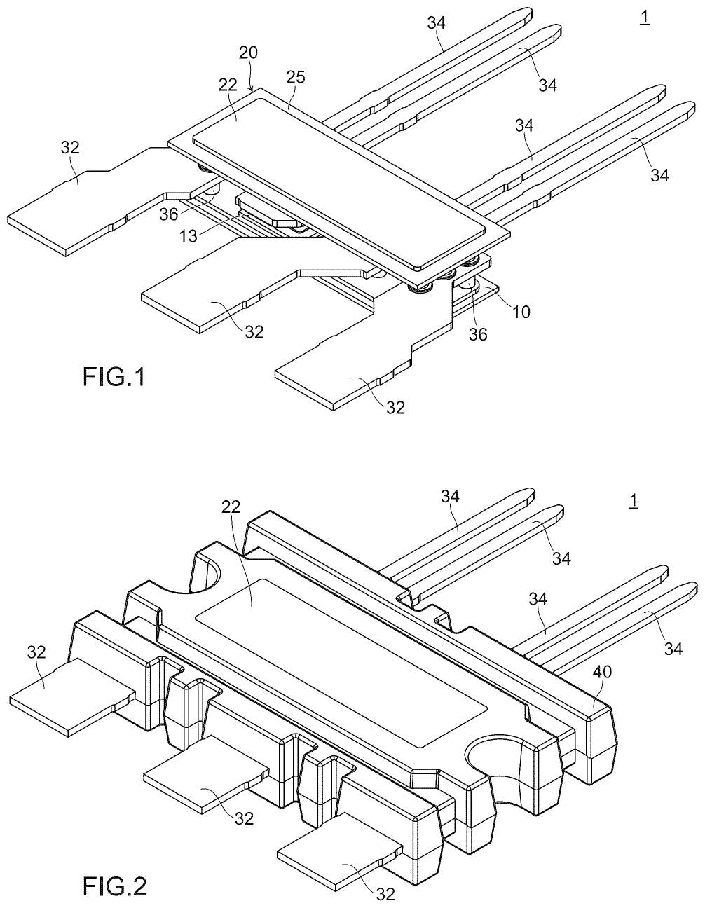

As illustrated in FIG. 1 to FIG. 3, the electronic module 1 according to an embodiment includes: a first board 10; a first heat radiation member 12; a first electronic element 13; a second board 20; a second heat radiation member 22; a second electronic element 23; a first external connection terminal 32; a second external connection terminal 34; and internal connection terminals 36: The electronic module 1 may include constitutional elements other than the above-mentioned constitutional elements. Hereinafter, the respective constitutional elements are described.

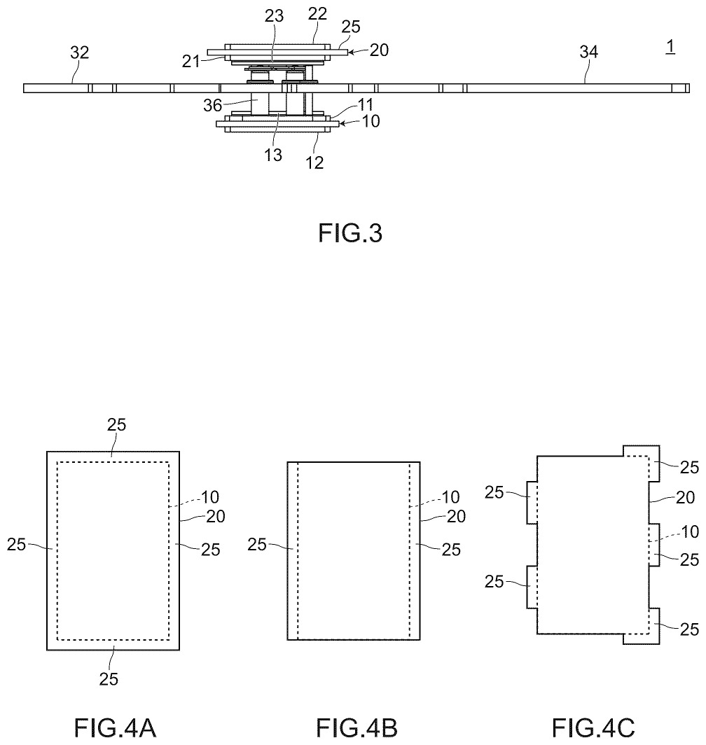

The first board 10 is a board where the first heat radiation member 12 is disposed on one surface and the first electronic element 13 is disposed on another surface (see FIG. 3). As the first board 10, a ceramic board can be used. It is preferred that a board having a structure where a copper plate is disposed on both surfaces of a ceramic plate (for example, DCB board) can be used as the first board 10. When a DCB board is used as the first board 10, the copper plate disposed on one surface can be used as a first heat radiation member 12. The first heat radiation member 12 is exposed to the outside of a mold resin 40. The first board 10 has a wiring 11 (see FIG. 3) and the wiring 11 is electrically connected to an electrode of the first electronic element 13.

In this specification, “electrically connected” includes not only a case where electricity supply portions of constitutional elements are directly in contact with each other but also a case where the constitutional elements are in contact with each other via an additional conductive constitutional element (for example, solder or a spacer).

The first electronic element 13 is an electronic element that is disposed on the first board 10. The first electronic element 13 is disposed on a second board 20 side of the first board 10, and is sealed by the mold resin 40. The first electronic element 13 has an electrode not illustrated in the drawing, and is electrically connected to the wiring 11 mounted on the first board 10 and the internal connection terminals 36. As the first electronic element 13, for example, a vertical type MOSFET can be exemplified.

The second board 20 is a board disposed on a side where the first electronic element 13 of the first board 10 is disposed in a state where the second board 20 is spaced apart from the first board 10 and the first electronic element 13. With respect to the second board 20, “a state where the first board 10 and the first electronic element 13 are spaced apart from the second board 20” means that the second board 20 is not in direct contact with the first board 10 and the first electronic element 13.

The second board 20 is a board where a second heat radiation member 22 is disposed on one surface and the second electronic element 23 is disposed on another surface. As the second board 20, a ceramic board can be used. It is preferred that a board having a structure where a copper plate is disposed on both surfaces of a ceramic plate (for example, DCB board) can be used as the second board 20. When a DCB board is used as the second board 20, the copper plate disposed on one surface can be used as a second heat radiation member 22. The second heat radiation member 22 is exposed to the outside of the mold resin 40 (see FIG. 2). The second board 20 has a wiring 21 (see FIG. 3) and the wiring 21 is electrically connected to an electrode of the second electronic element 23.

The second board 20 has, as viewed in a plan view, a protruding portion 25 that protrudes towards the outside from the outer periphery of the first board 10. In this embodiment, the protruding portion 25 means a portion where the second board 20 protrudes from the outer periphery of the first board 10 when the electronic module 1 is viewed in a plan view. It is preferred that the protruding portion 25 is formed of a ceramic board.

The shape of the protruding portion 25 and the number of the protruding portions 25 that the second board 20 includes can be suitably decided so long as the second board 20 can be supported in a stable manner during assembling of the electronic module 1. In such a configuration, “to support the second board 20 in a stable manner” includes not only a case where the second board 20 is supported by the protruding portions 25 but also a case where the second board 20 is supported by the protruding portions 25 and an internal connection terminal 35.

Hereinafter, the variations of the protruding portions 25 in the electronic module 1 are described with reference to FIG. 4A to FIG. 4C.

In the electronic module 1 according to the embodiment, the second board 20 is larger than the first board 10 in the longitudinal direction (vertical direction in the drawing) and in the lateral direction (in the left-and-right direction in the drawing) (see FIG. 4A). With such a configuration, when the first board 10 and the second board 20 are stacked such that the position of the center of gravity of the first board 10 and the position of the center of gravity of the second board 20 are aligned with each other, an outer periphery of the second board 20 is disposed outside an outer periphery of the first board 10 in all portions thus forming the protruding portion 25.

In a first modification, the second board 20 is formed such that a length in the lateral direction (the left-and-right direction in the drawing) is set longer than the first board 10 in the corresponding direction, and is formed with the same length as the first board 10 in the longitudinal direction (the vertical direction in the drawing) (see FIG. 4B). Accordingly, when the first board 10 and the second board 20 are stacked in the height direction such that the positions of the centers of gravity of the respective boards 10, 20 are aligned, the protruding portions 25 that protrude toward the outside from the outer periphery of the first board 10 are formed on the left side and the right side of the second board 20 in the drawing.

An outer shape of the first board 10 and an outer shape of the second board 20 are not limited to a rectangular shape. Either one or both of the first board 10 and the second board 20 may have shapes that differ from the rectangular shape. For example, in a second modification illustrated in FIG. 4C, as viewed in a plan view, an outer periphery of the second board 20 partially protrudes with respect to an outer periphery of the first board thus forming the protruding portions 25. In the second modification, in FIG. 4C, the protruding portions 25 are formed at five positions on sides of the second board 20. That is, two protruding portions 25 are formed at two positions on a left side of the second board 20, at one position from an upper side to a right side, at one position on the right side, and at one position from the right side to a lower side.

The above-mentioned shapes of the protruding portions 25 and the above-mentioned positions where the protruding portions 25 are formed are described in an exemplifying purpose, and are not limited to the above-mentioned shapes and positions. By providing the protruding portion 25 or the protruding portions 25 that are formed in a protruding manner toward the outside from the outer periphery of the first board 10 to the second board 20, this embodiment can acquire an advantageous effect that the first board 10 and the second board 20 can be mounted with high accuracy in a height direction.

The second electronic element 23 is an electronic element that is disposed on the second board 20. The second electronic element 23 is disposed on the second board 20 on a first board 10 side, and is sealed by the mold resin 40. The second electronic element 23 has an electrode, and is electrically connected to the wiring 21 disposed on the second board 20 and the internal connection terminals 36. As the second electronic element 23, for example, a vertical MOSFET can be exemplified.

The internal connection terminals 36 are disposed between the first board 10 and the second board 20. The internal connection terminal 36 is s formed as a columnar member, and functions as a member that adjusts a height of the second board 20 with respect to the first board 10. One end of the internal connection terminal 36 is disposed on the first board 10 or the first electronic element 13 disposed on the first board 10 via a bonding material (for example, solder). Further, the other end of the internal connection terminal 36 is disposed on the second board 20 or the second electronic element 23 disposed on the second board 20 via a bonding material (for example, solder).

The internal connection terminal 36 is a member that is used for electrical transaction in the electronic module 1 simultaneously. One end of the internal connection terminal 36 is electrically connected to the wiring 11 of the first board 10 or an electrode of the first electronic element 13. The other end of the internal connection terminal 36 is electrically connected with the wiring 21 of the second board 20 or an electrode of the second electronic element 23. Further, the internal connection terminal 36 is electrically connected with the first external connection terminal 32 or the second external connection terminal 34. By taking into account an amount of current that flows into the internal connection terminal 36, it is preferred that a cross-sectional area and a material of the internal connection terminal 36 is selected, and the number of the internal connection terminals 36 to be used is selected.

The first external connection terminal 32 is a terminal that connects the wiring 11 of the first board 10, the electrode of the first electronic element 13, the wiring 21 of the second board 20 or the electrode of the second electronic element 23 with the outside of the electronic module 1 via the internal connection terminal 36. The first external connection terminal 32 is a power terminal corresponding to a large current. The first external connection terminal 32 is configured such that at least one end of the first external connection terminal 32 is exposed to the outside of the mold resin 40, and is capable of being connected with an external terminal not illustrated in the drawing.

The second external connection terminal 34 is a terminal that connects the wiring 11 of the first board 10, the electrode of the first electronic element 13, the wiring 21 of the second board 20 or the electrode of the second electronic element 23 with the outside of the electronic module 1 via the internal connection terminal 36. The second external connection terminal 34 is electrically connected with the internal connection terminal 36 between the first board 10 and the second board 20. The second external connection terminal 34 is configured such that at least one end of the second external connection terminal 34 is exposed to the outside of the mold resin 40, and is capable of being connected with an external terminal not illustrated in the drawing.

The mold resin 40 seals a surface of the first board 10 on a side where the first electronic element 13 is disposed and the first electronic element 13 (see FIG. 2). Further, the mold resin 40 seals a surface of the second board 20 on a side where the second electronic element 23 is disposed and the second electronic element 23.

### 2. Method of Manufacturing Electronic Module

The method of manufacturing the electronic module 1 according to the embodiment is described.

### 2.1. Assembly Jig

The electronic module 1 according to the embodiment manufactures by arranging the first board 10, the internal connection terminal 36, the first external connection terminal 32, the second connection terminal 34 and the second board 20 in a height direction using an assembly jig 50.

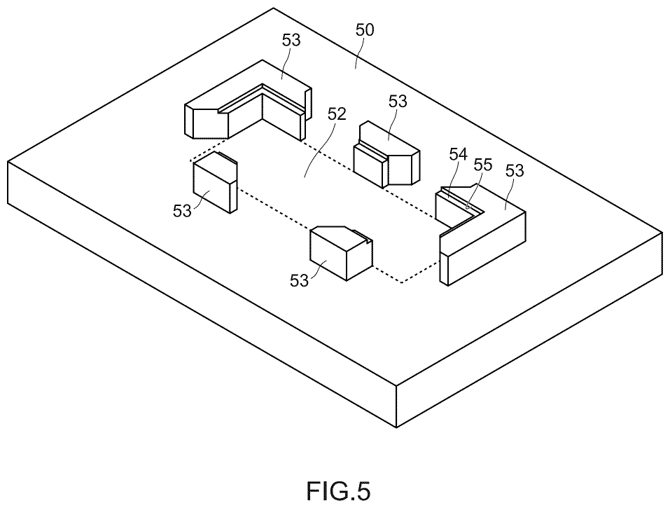

The assembly jig 50 that can be used in the manufacture of the electronic module 1 includes, as illustrated in FIG. 5, a first mounting portion 52, raised portions 53, second mounting portions 54, and walls 55.

The first mounting portion 52 is a flat surface formed on the assembly jig 50 is formed, and is a mounting portion on which the first board 10 is mounted. In FIG. 5, the first mounting portion 52 is indicated as a region that is surrounded by a solid line and a dotted line. By mounting the first board 10 on the first mounting portion 52, a height of the first board 10 can be adjusted using the surface on which the first mounting portion 52 is formed as a reference surface.

The raised portions 53 are arranged around the first mounting portion 52. In the assembly jig 50 illustrated in FIG. 5, five raised portions 53 are disposed. Further, as viewed in a plan view, each raised portion 53 is arranged to be in contact with a boundary between the first mounting portion 52 and a region outside the first mounting portion 52. With such a configuration, when the first board 10 is mounted on the first mounting portion 52, the free movement of the first board 10 in-plane direction is restricted and hence, the positioning of the first board 10 in the in-plane direction can be performed.

In the electronic module 1, the raised portions 53 are disposed while avoiding the positions at which the first external connection terminals 32 and the second external connection terminals 34 are arranged.

The raised portion 53 includes the second mounting portion 54. The second mounting portion 54 is a mounting portion that engages with and stopes the protruding portion 25 of the second board 20 at the time of deciding the height of the second board 20. The second mounting portion 54 is formed on a surface of the raised portion 53 that faces the first mounting portion 52. When the second board 20 is mounted on the assembly jig 50, the second mounting portion 54 is disposed at the position that corresponds to the protruding portion 25 of the second board 20. The second mounting portion 54 is disposed at the position having a predetermined height using the first mounting portion 52 as a reference. In arranging the the second board 20 on the second mounting portion 54, by allowing the protruding portion 25 to be engaged with and to be stopped by the second mounting portion 54, the second board 20 can be implemented in the height direction with high accuracy with respect to the reference surface of the first mounting portion 52.

The raised portion 53 has the wall 55. The wall 55 is disposed at the position at which the free movement of the second board 20 in the in-plane direction is restricted in a state where the protruding portion 25 is engaged with and is stopped by the second mounting portion 54. With such a configuration, when the second board 20 is mounted on the second mounting portion 54, it is possible to perform the positioning of the second board 20 in the in-plane direction.

### 2.2 Method of Manufacturing Electronic Module

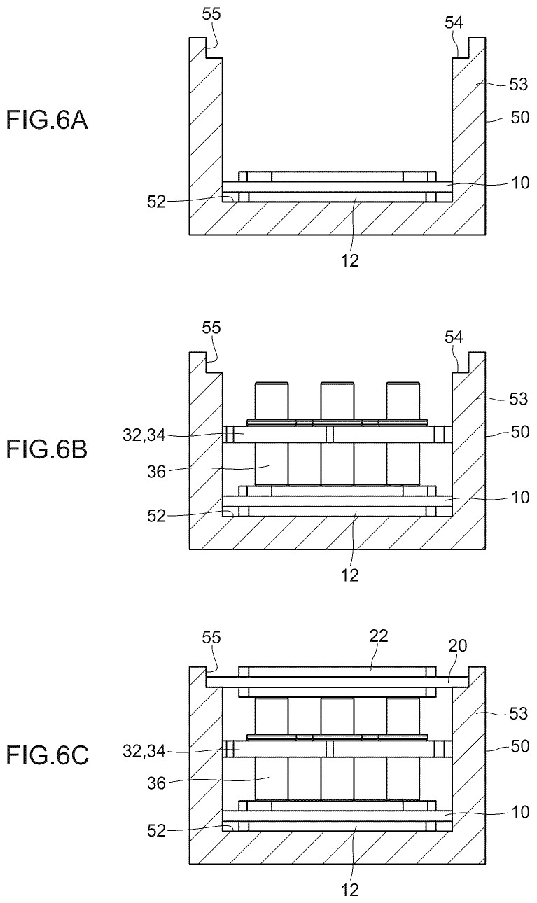

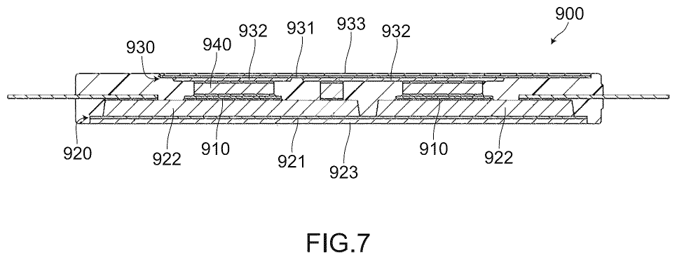

Next, the method of manufacturing an electronic module is described with reference to FIG. 6A to FIG. 6C.

The method of manufacturing the electronic module 1 includes: a first board mounting step of mounting the first board 10 on the first mounting portion 52 of the assembly jig 50; an internal connection terminal mounting step of mounting one end of the internal connection terminal 36 on the first board 10; and a second board mounting step of mounting the second board 20 on the other end of the internal connection terminal 36 and the second mounting portion 54.

In the method of manufacturing the electronic module 1, when the second board 20 is assembled as a part of the electronic module 1, as viewed in a plan view, the second board 20 includes the protruding portion 25 that protrudes toward the outside from the outer periphery of the first board 10. The second board 20 is mounted on the second mounting portion 54 in a state where the protruding portion 25 is engaged with and is stopped by the second mounting portion 54.

Further, in the method of manufacturing the electronic module 1, the second mounting portion 54 is disposed at the predetermined height position from the first mounting portion 52. Further, the second mounting portion 54 is disposed at the position where the protruding portion 25 is engaged with and is stopped by the second mounting portion 54 as viewed in a plan view.

Hereinafter, the method of manufacturing the electronic module 1 is described in detail.

The assembly jig 50 is prepared. The assembly jig 50 that can be used in the method of manufacturing the electronic module 1 includes, as illustrated in FIG. 5 and FIG. 6A to FIG. 6C, the first mounting portion 52 on which the first board 10 is mounted, the raised portion 53, and the second mounting portion 54 on which the second board 20 is mounted.

The raised portions 53 are disposed at positions that allow the first board 10 to pass between the raised portions 53 from above when the first board 10 is mounted on the first mounting portion 52. The second mounting portion 54 is disposed on the raised portion 53, and is disposed at a predetermined height position using the first mounting portion 52 as the reference. Further, the second mounting portion 54 is, as viewed in a plan view, disposed at the position where the protruding portion 25 is engaged with and is stopped by the second mounting portion 54.

In the first board mounting step, as illustrated in FIG. 6A, the first board 10 is mounted on the first mounting portion 52 on the assembly jig 50. When the first board 10 is mounted on the first mounting portion 52, the raised portions 53 that include the second mounting portions 54 are disposed at the positions that allow the first board 10 to pass between the raised portions 53 as viewed in a plan view. With such arrangement, it is possible to make the first board 10 to pass between the raised portions 53 and the first board 10 can be mounted on the first mounting portion 52.

The first board 10 is mounted such that the surface on which the first heat radiation member 12 is disposed is brought into contact with the first mounting potion 52. With such arrangement, it is possible to make the height of the surface that the first heat radiation member 12 of the first board 10 is disposed align with the height of the reference surface of the first mounting portion 52. Further, the outer periphery of the first board 10 is brought into contact with the internal peripheries of the raised portions 53 of the assembly jig 50. With such a configuration, it is possible to prevent free movement of the first board 10 in the in-plane direction. As a result, the positioning of the first board 10 in the in-plane direction can be performed.

As illustrated in FIG. 6B, in the internal connection terminal mounting step, the internal connection terminals 36 are raised on the first board 10. Subsequently, the first external connection terminal 32 and the second external connection terminal 34 are disposed. Alternatively, in place of the above-mentioned steps, the internal connection terminals 36 are made to pass through holes formed in the first external connection terminal 32 or the second external connection terminal 34, and the structure where the internal connection terminal 36 and the first external connection terminal 32 and/or the second external connection terminal 34 are assembled is prepared. Further, the structure where the internal connection terminal 36 and the first external connection terminal 32 and/or the second external connection terminal 34 are assembled may be disposed on the first board 10.

As illustrated in FIG. 6C, in the second board mounting step, the second board 20 on which the second electronic element 23 (see FIG. 3) is mounted on the other end of the internal connection terminal 36 and the second mounting portion 54. The second board 20 includes the protruding portion 25. By allowing the protruding portion 25 to be engaged with and to be stopped by the second mounting portion 54, the second board 20 can be mounted on the second mounting portion 54. Accordingly, the height of the second board 20 can be adjusted using the height of the first mounting portion 52 as the reference.

Further, the outer periphery of the second board 20 is brought into contact with the wall 55. Accordingly, it is possible to restrict the free movement of the second board 20 in the in-plane direction when the second board 20 is mounted on the second mounting portion 54. As a result, it is possible to perform the positioning of the second board 20 in the in-plane direction.

After the second board 20 is mounted, the assembled structure is sealed by a mold resin 40 thus completing the electronic module 1. The resin sealing is performed as follows. The surface of the first board 10 on a side where the first electronic element 13 is disposed and the first electronic element 13 are sealed by the mold resin 40. Further, the surface of the second board 20 on a side where the second electronic element 23 is disposed and the second electronic element 23 are sealed by the mold resin 40.

Hereinafter, advantageous effects acquired by the electronic module 1 according to the embodiment are described.

The electronic module 1 according to the embodiment includes the first board 10, the second board 20, and the internal connection terminal 36 that connects the first board 10 and the second board 20 to each other. The second board 20 has, as viewed in a plan view, the protruding portion 25 that protrudes more toward the outside than the outer periphery of the first board 10. According to the electronic module 1, due to the provision of the heat radiation surface of the first board 10 and the protruding portion 25 of the second board 20, the first board 10 and the second board 20 can be mounted with high accuracy in the height direction. Accordingly, it is possible to provide the electronic module 1 that possesses an excellent heat radiation characteristic.

In the electronic module 1 according to the embodiment, the second board 20 includes the ceramic board and the second heat radiation member 22 formed on one surface of the ceramic board, and the protruding portion 25 is formed of a ceramic board. By adopting a ceramic board as the second board 20, the first board 10 and the second board 20 can be mounted with high accuracy in the height direction and, at the same time, a heat radiation characteristic from the second board 20 side can be enhanced. Further, by forming the second heat radiation member 22 on the surface of the second board 20, a heat radiation characteristic can be further enhanced. Accordingly, it is possible to provide the electronic module 1 that possesses an excellent heat radiation characteristic.

In the electronic module 1 according to the embodiment, the first board 10 includes the ceramic board and the first heat radiation member 12 that is formed on one surface of the ceramic board. By adopting the ceramic board as the first board 10, the first board 10 and the second board 20 can be mounted with high accuracy in the height direction and, at the same time, a heat radiation characteristic from the first board 10 side can be enhanced. Further, by forming the first heart radiation member 12 on one surface of the first board 10, the heat radiation characteristic can be further enhanced. Accordingly, it is possible to provide the electronic module 1 that possesses the excellent heat radiation characteristic.

The electronic module 1 according to the embodiment further includes the first external connection terminal 32 and/or the second external connection terminal 34, and the internal connection terminal 36 is made to pass through the first external connection terminal 32 and/or the second external connection terminal 34. By accurately controlling a length of the internal connection terminal 36, the first board 10 and the second board 20 can be mounted with high accuracy in the height direction. Further, the first electronic element 13 or the second electronic element 23 can be electrically connected to the first external connection terminal 32 or the second external connection terminal 34.

The method of manufacturing the electronic module 1 according to the embodiment includes: a first board mounting step of mounting the first board 10 on the first mounting portion 52 of the assembly jig 50 that includes the first mounting portion 52 on which the first board 10 is mounted and the second mounting portion 54 on which the second board 20 is mounted; and the second board mounting step of mounting the second board 20 on the second mounting portion 54. The second board 20, when the second board 20 is assembled as a part of the electronic module 1, includes the protruding portion 25 that protrudes more outside than the outer periphery of the first board 10 as viewed in a plan view. The second mounting portion 54 is disposed at the predetermined height position from the first mounting portion 52, and is disposed at the position where the protruding portion 25 is engaged with and is stopped by the second mounting portion 54 as viewed in a plan view. With such a configuration, the first board 10 and the second board 20 can be mounted in the height direction with high accuracy. According to the present invention, in the electronic module 1 where a heat radiation surface is formed on both surfaces of the electronic module 1, the heat radiation surface can be mounted in the height direction with high mounting accuracy and hence, it is possible to provide the method of manufacturing the electronic module 1 which possesses excellent heat radiation characteristic.

The present invention has been described based on the above-mentioned embodiments heretofore, the present invention is not limited to the above-mentioned embodiment. The present invention can be carried out in various modes without departing from the gist of the present invention. For example, the following modifications are also conceivable.
(1) The shape, the numbers, the sizes, the positions and the like of the constitutional elements according to the present invention are not limited to the values illustrated in the above-mentioned description and the respective drawings, and the values can be suitably changed so long as the technical feature of the present invention are not impaired.

To exemplify one example, in the above-mentioned embodiment, although the number of the first electronic elements 13 and the number of the second electronic elements 23 are respectively one, the present invention is not limited to such a case. The number of the first electronic elements 13 and the number of the second electronic elements 23 may be plural.
(2) The electronic module according to the present invention may further include electronic elements, structures and the like besides the first electronic element 13 on the first board 10. Further, the electronic module according to the present invention may further include electronic elements, structures and the like besides the second electronic element 23 on the second board 20.
(3) As the first electronic element 13 in the electronic module according to the present invention, electronic elements other than a MOSFET (for example, various types of diodes, transistors other than a vertical MOSFET, a thyristor) can be also used. The same goes for the second electronic element 23.

1. An electronic module comprising:
a first board;
a first electronic element that is disposed on the first board;
a second board;
a second electronic element that is disposed on the second board; and
an internal connection terminal that is disposed between the first board and the second board, wherein
the second board includes a protruding portion that protrudes more outside than an outer periphery of the first board as viewed in a plan view.

2. The electronic module according to claim 1, wherein
the second board has a ceramic board and a heat radiation member that is formed on one surface of the ceramic board, and
the protruding portion is formed of a part of the ceramic board.

3. The electronic module according to claim 2, wherein
the first board includes a ceramic board member and a heat radiation member that is formed on one surface of the ceramic board.

4. The electronic module according to claim 1, further comprising an external connection terminal, wherein
the internal connection terminal is configured to pass through the external connection terminal.

5. A method of manufacturing an electronic module using an assembly jig that includes a first mounting portion and a second mounting portion, the method comprising:
a first board mounting step of mounting a first board on the first mounting portion;
an internal connection terminal mounting step of mounting one end of an internal connection terminal on the first board; and
a second board mounting step of mounting the second board on an other end of the internal connection terminal and the second mounting portion, wherein
the second board has a protruding portion that protrudes more outside than an outer periphery of the first board as viewed in a plan view when the second board is assembled as a part of the electronic module,
the second board is mounted on the second mounting portion in a state where the protruding portion is engaged with and is stopped by the second mounting portion, and
the second mounting portion is disposed at a predetermined height position from the first mounting portion, and is disposed at a position where the protruding portion is engaged with and is stopped by the second mounting portion as viewed in a plan view.
